(19) United States
(12) Patent Application Publication
(10) Pub. No.: US 2025/0393171 A1
(43) Pub. Date: Dec. 25, 2025

(54) DIRECT RAPID AIR-COOLING SYSTEM FOR SERVER CADDY ARRAYS

(71) Applicant: Zoho Corporation Private Limited, Kanchipuram District (IN)

(72) Inventors: Yash Manoj Kadu, Nagpur (IN); Animesh Anil Admane, Nagpur (IN); Mangesh Devidas Sadafale, Nagpur (IN)

(73) Assignee: Zoho Corporation Private Limited, Kanchipuram District (IN)

(21) Appl. No.: 19/213,443

(22) Filed: May 20, 2025

Related U.S. Application Data
(60) Provisional application No. 63/682,960, filed on Aug. 14, 2024.

(30) Foreign Application Priority Data
Jun. 25, 2024 (IN) 202441048667
Jun. 26, 2024 (IN) 202441049035

(51) Int. Cl. H05K 7/20

(52) U.S. Cl. CPC H05K 7/20736; H05K 7/20145

(57) ABSTRACT

A server chassis comprises banks of caddies defining an airflow channel between them through which fans draw air. One or more crossmembers traverse the airflow channel and support the weight of caddy banks. A unitary air-diversion device comprises first and second baffles angled to direct air flow in first and second directions and an attachment for affixing it to a crossmember. The air-diversion device is disposed within the airflow channel to divert drawn air to a caddy bank in one direction and to another caddy bank in another direction, allowing drawn air to pass above, below, and/or through the baffles to continue moving in the airflow channel. A guideway assembly, operable with the server chassis, comprises sets of caddies engaged between guideways having channels configured to engage with the sets of caddies. A guideway channel remains vacant between the caddies to define an airflow channel in which the air-diversion device can be attached to direct air flow to the banks of caddies.

### CROSS REFERENCE TO RELATED APPLICATIONS

This application is related to Indian Provisional Application 20/244,1049035, filed 26 Jun. 2024, and U.S. Provisional Application 63/682,960 filed 14 Aug. 2024, both entitled “DIRECT RAPID AIR-COOLING SYSTEM FOR SERVER CADDY ARRAYS”, both of which are incorporated herein by reference.

### FIELD OF THE INVENTION

Embodiments of the present disclosure are related, in general, to data servers and more particularly, but not exclusively, to server drive cooling.

This application is also related to Indian Provisional Application 20/244,1048667, filed 25 Jun. 2024, and U.S. Provisional Application 63/682,947 filed 14 Aug. 2024, both entitled “TOP-LOADING DRIVE CADDY AND GUIDEWAY MOUNTING”, both of which are incorporated herein by reference.

### BRIEF DESCRIPTION OF THE DRAWINGS

The subject matter disclosed is illustrated by way of example, and not by way of limitation, in the figures of the accompanying drawings and in which like reference numerals refer to similar elements and in which:

FIGS. 1A-1D depict various views of a drive caddy 10 that receives and supports a storage drive.

FIG. 2 depicts a guideway 40, which is compatible with caddies 10.

FIGS. 3A-3H illustrate various views of the use of caddies 10 and guideways 40 in a guideway assembly 70.

FIGS. 4A-4C illustrates caddies 10 and guideways 40 in an example server chassis, including airflow channels 210 and air-diversion devices 200.

FIG. 5 is an example air-diversion device 200.

FIGS. 6A-6C show thermal simulation results for the example chassis 100 with and without the Direct Rapid Air-cooling System implementation, respectively.

### DETAILED DESCRIPTION

Drive caddies, also known as drive trays or drive carriers, are essential components in server environments. They are used to house and secure hard drives (HDDs) or solid-state drives (SSDs), collectively “storage drives” or just “drives,” in a server chassis. Many servers support hot-swappable drives, allowing drives to be replaced or added without powering down the server.

Drive caddies are available for different form factors, typically 2.5-inch and 3.5-inch drives, matching the common sizes of HDDs and SSDs. By using appropriate drive caddies, server administrators can efficiently manage storage devices, ensuring reliability, ease of maintenance, and scalability in their server environments.

A server chassis can be configured to house sets of caddies and can be customized to take advantage of the design features of the caddy. When a server chassis is loaded with caddies, each caddy housing a hard drive, and the hard drives are operational, it is important to have proper ventilation and cooling to keep the electronics within operational temperature specifications. Generally, cooler operating temperatures translate into fewer hardware failures and reduced operational cost.

The Direct Rapid Air-cooling System (DRAS) provides airflow through two or more air channels to efficiently dissipate heat, diverting a portion of the channel airflow as needed based on location within an array of storage drives. The DRAS system provides proper cooling facilitating reliable operation without complexity and maintenance concerns. Straightforward construction allows for simple cost-effective manufacturing and installation.

A server chassis is disclosed comprising a first and second bank of caddies that can house storage drives, each bank comprising a plurality of caddies, the banks defining an airflow channel between them. A plurality of fans disposed at one end of the airflow channel draw air flow from the opposite end of the airflow channel. The chassis includes an air-diversion device comprising a first baffle and a second baffle, the first baffle angled to direct air flow in a first direction, the second baffle angled to direct air flow in a second direction.

One or more crossmembers traverse the airflow channel, support the weight of the two banks of caddies, and connect the air-diversion device, disposed within the airflow channel, to divert a first portion of the drawn air to the first bank of caddies in the first direction, to divert a second portion of the drawn air to the second bank of caddies in the second direction, and to allow a third portion of the drawn air to pass above or below the first and second baffles to continue moving in the airflow channel. The air-diversion device may further comprise an aperture defined by an edge of the first baffle and an edge of the second baffle, wherein the third portion of the drawn air includes air drawn through the aperture. The server chassis may further comprise one or more additional banks of caddies to define one or more additional airflow channels, with an additional air-diversion device disposed within each additional airflow channel.

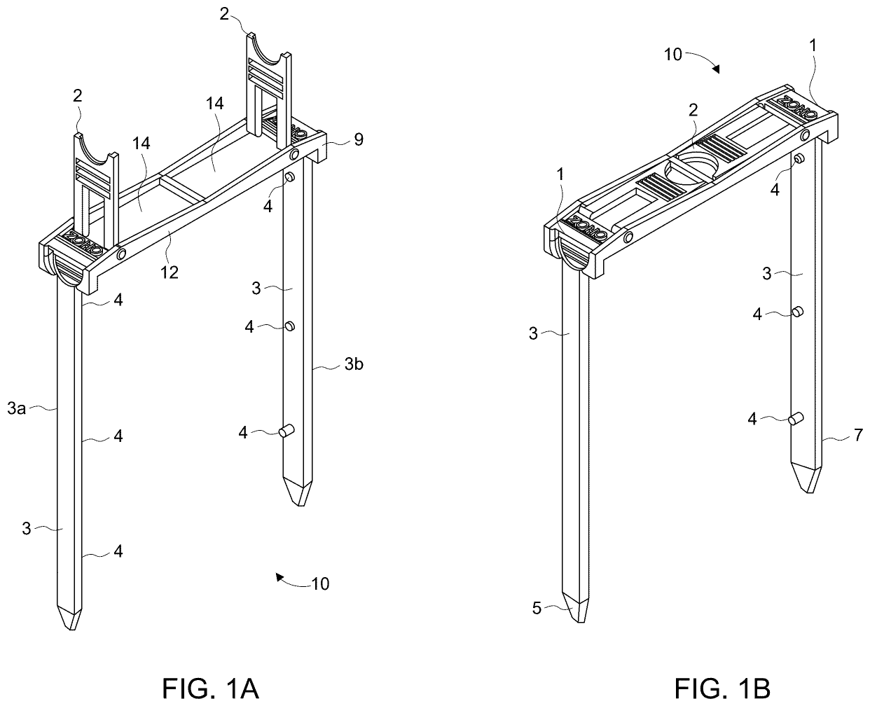

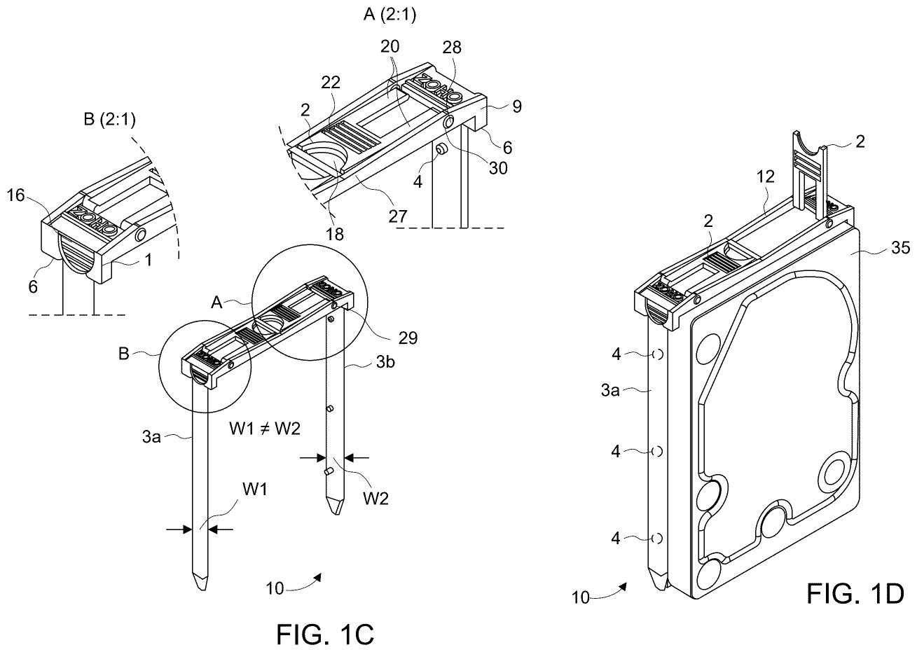

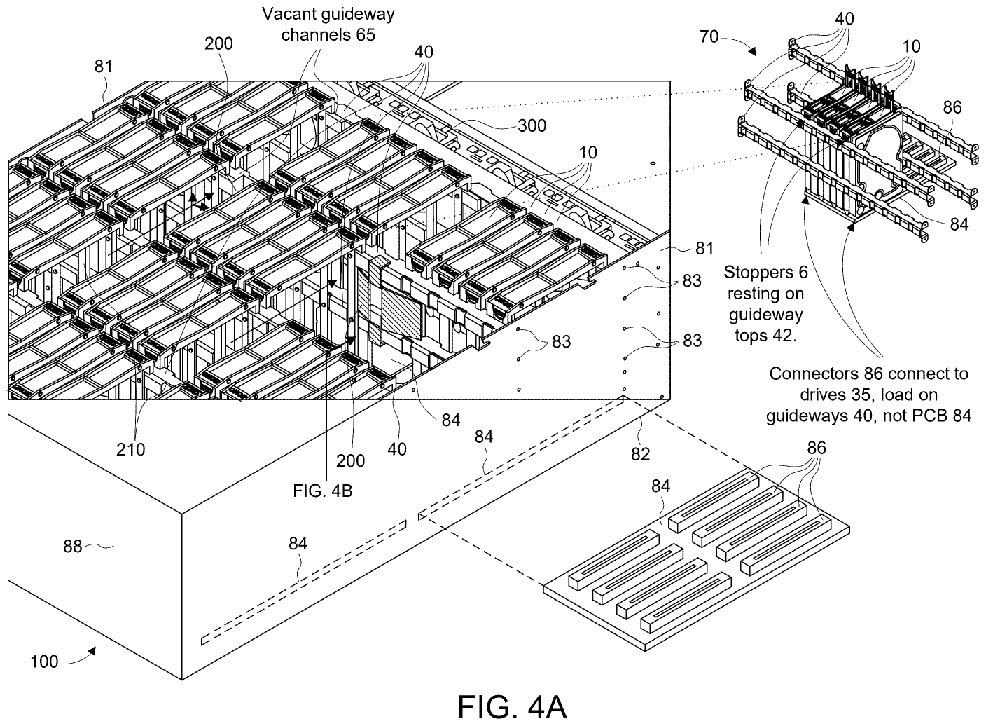

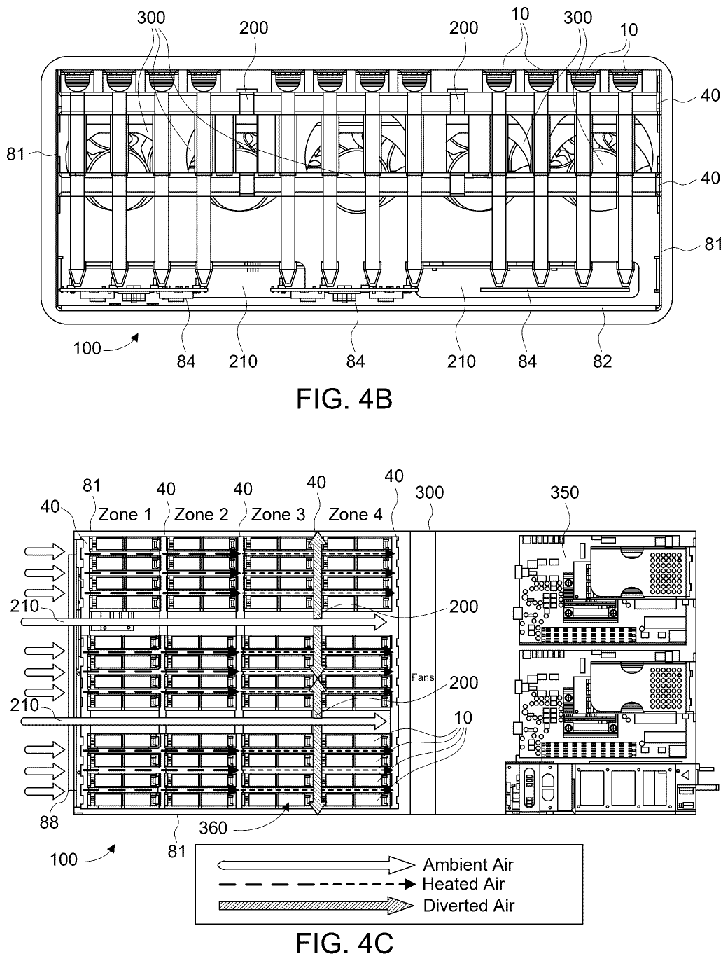

An example server chassis 100 is illustrated in FIGS. 4A-4C. An array of drives 360 is included (detailed in FIG. 4C). In this example, the drives 35 are housed in caddies 10, which are mounted on sets of guideways 40 (serving as server chassis crossmembers in this embodiment). 4 rows of 12 caddies 10 house 48 drives 35. 5 sets of guideways 40 are deployed to support the 4 rows of caddies and drives. Here, the guideways 40 have 14 sets of guideway channels 65. The 12 caddies in each row are inserted in groups of 4, using 12 of the 14 guideway channels 65. Two airflow channels 210 are formed by leaving the 5th and 10th guideway channels vacant of caddies. Example embodiments of caddies and compatible guideways are detailed below with respect to FIGS. 1-3. Alternate caddies and insertion systems, as well as differing drive array sizes may be deployed in alternate embodiments.

Fans 300 are deployed to blow air over hot parts like CPUs and GPUs, identified in FIG. 4C as server processing hardware 340. The server systems are cooled using forced air-cooling systems in which conditioned room air is forced, by one or more fans 300 through airflow channels 210, over server processing hardware 350, e.g. finned heat sinks mounted on microprocessors, power supplies, and other electronic devices.

The drive array 360 is divided into four main zones, as labeled in FIG. 4C. The drives in zone one and zone two are cooled conventionally with the air drawn in at 25° C. (ambient air temperature). For the zones farther back, cold air is drawn straight from the front into the center of the drawer via air flow channels 210 and distributed through the third zone and fourth zone with help of baffles 215 affixed to air-diversion devices 200. Fans 300 also draw air through the drive array 360.

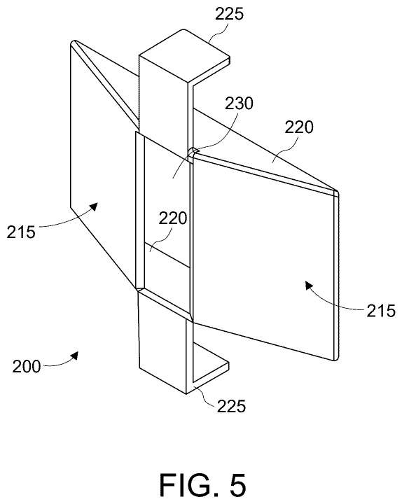

An example air-diversion device 200 is detailed in FIG. 5. This example uses injection molded plastic for low cost and simple installation. It comprises baffles 215 (angular in this embodiment, but alternate shapes which divert air may be substituted). An aperture 230 is formed by the edges off each baffle 215 and sides 220. The aperture can be of any size, and an aperture of size zero is supported, in which case the two baffles are conjoined on those edges. The shape of the aperture is rectangle as illustrated in FIG. 5. In other embodiments, the shape of the aperture can be square, cuboid, or any other geometric shape allowing air to pass.

The height of the baffles relative to the height of the airflow channels determines how much of the air flow can pass above or below the baffles. The two baffles are angled to divert air in first and second directions. In a cross-section of the airflow channel, the baffles define a diversion surface area, which is a function of the shape and surface area of each baffle and the angle defined by the baffle angle and the cross-section. The aperture defines an aperture surface area, which may be zero. The area above and below air-diversion device 200, if any, defines a bypass surface area. The ratio of the diversion surface area to the sum or the aperture and bypass surface areas determines the fraction of air diverted to zones three and four and that which is delivered straight to the server processing hardware 350. Brackets 225 are deployed which are sized to allow air-diversion device 200 to be simply clipped to a pair of guideways 40, as shown. Alternate attachments may be supplied to affix the air-diversion device 200 to a guideway or other crossmember in alternate embodiments.

FIGS. 4A-C illustrate caddies 10 and guideways 40 in an example server chassis, in this case illustrated in a drawer 100. FIG. 4A is a perspective view of server chassis drawer 100. It has two sides 81 and a front 88 shown. Additional processing components and the back of the drawer are not shown in FIG. 4A for simplicity. Guideways 40 are attached to each side 81 via attachments 83. In this example, attachments 83 are machined screw holes, which allow screws (not shown) to be inserted through holes 56 and screwed into those attachment holes. The caddies in the main portion of the figure are shown inserted without drives to allow visibility to the other components, such as Printed Circuit Boards (PCBs) 84 shown attached to the drawer bottom 82 (positions illustrated by hidden lines identifying two rows of PCBs 84).

In this example, each PCB 84 accepts 4 drives (in caddies) from one row and 4 drives (in caddies) from a neighboring row. Each PCB 84 has 8 drive connectors 86 as shown. The PCBs will be connected to the server components (details not shown). In this configuration, there are 4 rows of 12 caddies for a total of 48 drives. 5 sets of two guideways 40 are utilized, 3 in the middle of the rows, and two on the ends. Airflow channels 210 are formed by leaving vacant some of the channels/notches 65 on the sets of guideways 40. Airflow is also possible through the caddies as well. Fans 300 draw air from the front of the chassis through the caddies 10, the hard drives 35, and the airflow channels 210 to the rear of the chassis.

An example guideway assembly 70 (detailed below) is shown with caddies 10 including drives 35. As shown, the caddies 10 are inserted with stoppers 6 resting on guideway tops 42 of the top guideways 40 (the guideways serving as crossmembers). The drives are connected to the PCB 84 through connectors 86, but the load is on the guideways 40, not PCB 84.

FIG. 4B shows a cross section of server chassis 100, with empty caddies 10 for illustrative purposes. Guideways 40, fixed to sides 81, support the plurality of caddies 10, which are by design in appropriate positions above PCBs 84 such that, when inserted, drives 35 will connect to the PCBs 84. The PCBs 84 are affixed to drawer bottom 82. Fans 300 pull air through the server chassis 100.

FIG. 4C is a top view of server chassis 100. Ambient, heated, and diverted airflow are shown, as identified in the legend. Ambient air is shown as a large hollow arrow. Air heating is depicted by the arrows with dotted lines changing. The air diverted by air-diversion device 200 is depicted with cross-hatched arrows.

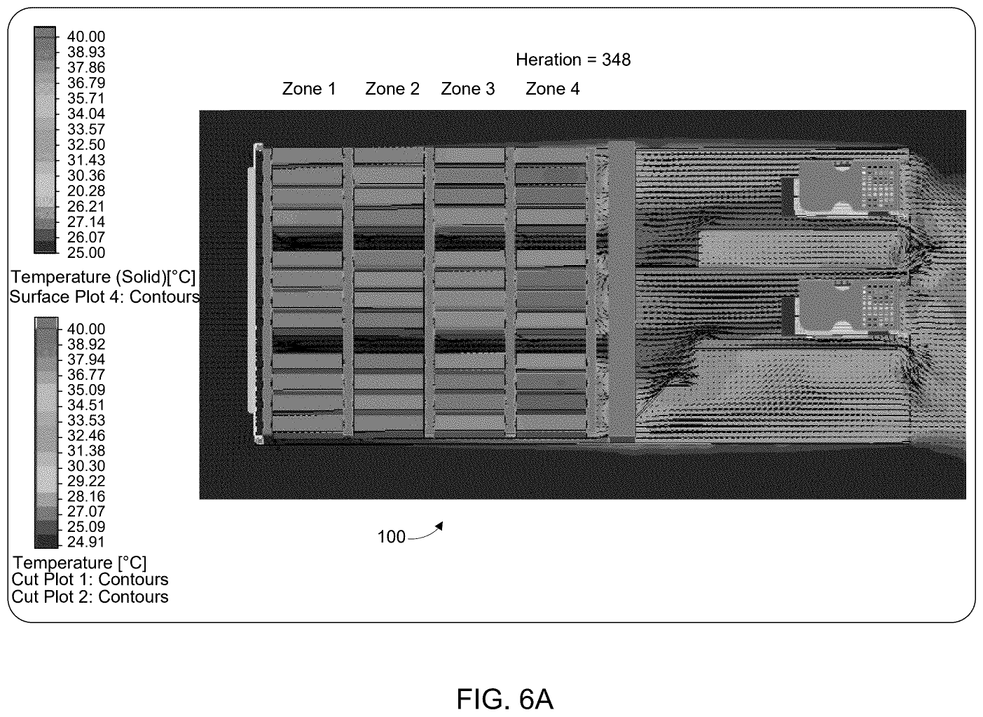

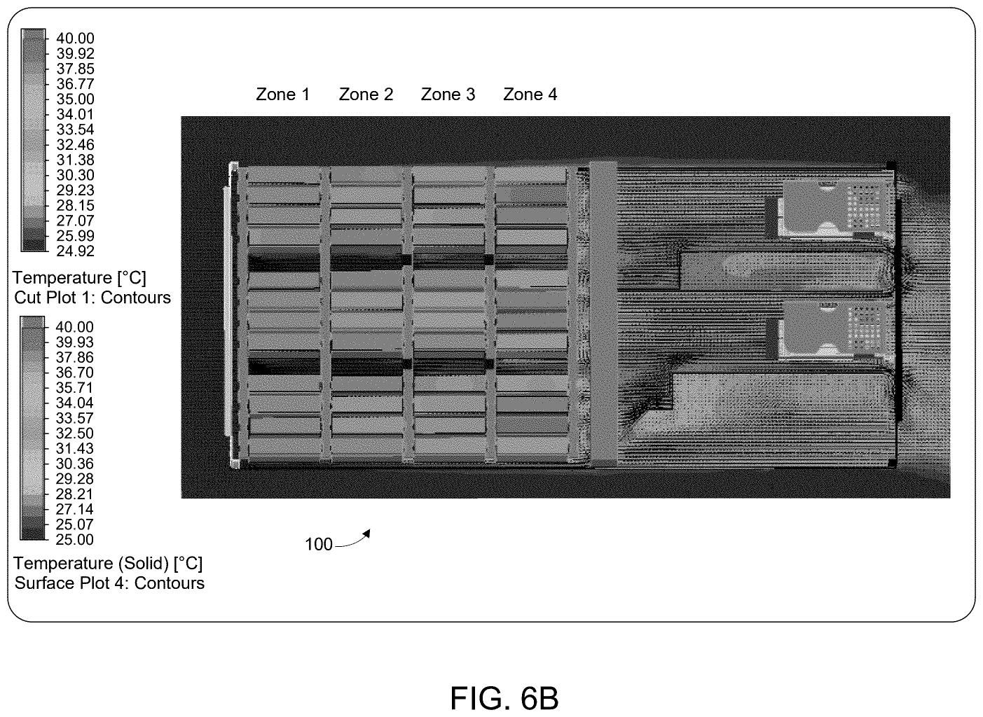

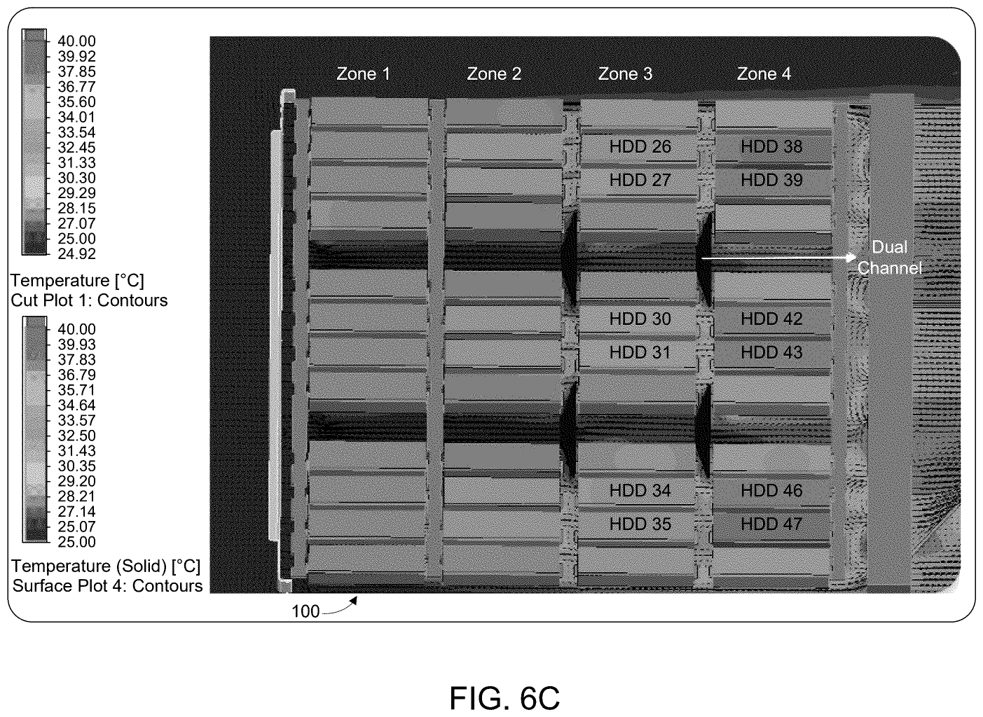

FIGS. 6A-C show thermal simulation results for the example chassis 100 with and without the DRAS implementation. FIG. 6A shows the results without DRAS. FIG. 6B shows the results with DRAS. FIG. 6C shows specific hard drives and the effects on them by the DRAS implementation.

| | | Without DRAS | With DRAS |
|---|---|---|---|
| Zones | HDD No. | Flow | Flow |
| Zone 3 | HDD 26 | 37.32 | 36.7 |
| | HDD 27 | 37.27 | 36.22 |
| | HDD 30 | 36.73 | 35.84 |
| | HDD 31 | 36.9 | 35.97 |
| | HDD 34 | 37.3 | 36.25 |
| | HDD 35 | 37.54 | 36.84 |
| Zone 4 | HDD 38 | 38.49 | 37.75 |
| | HDD 39 | 38.22 | 37.36 |
| | HDD 43 | 38.24 | 37.17 |
| | HDD 46 | 38.45 | 37.57 |
| | HDD 47 | 38.68 | 37.86 |

Table. 1.1. Thermal Result Comparison with DRAS and without DRAS

The analytical study resulted in a notable decrease in temperature for the hard drives situated in zones 3 and 4. The Direct Rapid Airflow System (DRAS) flow predominantly impacts zone 3 (HDD25 to HDD36) and zone 4 (HDD37 to HDD46), consequently influencing the thermal dynamics in these zones.

Table 1.1 illustrates a temperature reduction of approximately 2 degrees, indicating an enhancement in the overall cooling efficiency of the system. This improvement will result in improving the lifespan of the hard drives, thereby optimizing the reliability and performance of the storage server.

The DRAS Flow or Direct Rapid Air-cooling System stands out by optimizing airflow through dual channels, providing a more focused and efficient cooling mechanism for high-performance server components. This solution offers the benefits of enhanced cooling efficiency, reduced risk of overheating, and reliable server operation without the complexities associated with liquid cooling systems.

Example caddies and guideways suitable for deployment in the example embodiment are described below and detailed further in co-pending provisional application <<<Cross reference to ZH051 application>>>, which is incorporated herein by reference.

FIGS. 1A-1D depict a drive caddy 10 that receives and supports a storage drive. One or more such drive caddies can be installed in a computer system, such as a server. The caddy is adapted to be inserted into a top-loading server chassis. Its unidirectional hot-swap screwless design allows it to be inserted into the chassis achieving correct alignment, avoiding incorrect guiding which can lead to physical damage, data loss, and hardware failure. The caddy is a protective robust enclosure which safeguards the drive from physical damage. It is designed for hot swapping which reduces maintenance costs by minimizing the need for system shutdowns. The need for additional tools or locking mechanisms is eliminated, reducing overall equipment costs.

FIG. 1A shows caddy 10 comprising three parts: a caddy body 9 and two handles 2. The caddy body 9 comprises a caddy body crossmember 12 and two sides 3 which also serve as guides 3a and 3b. The handles 2 are depicted in the extended, or open, position, outside of handle receptacles 14. FIG. 1B shows caddy 10 with the handles 2 closed into handle receptacles 14. Caddy body 9 and each handle 2 are of unitary construction, which is to say they are each made of a single piece of material. The pieces can be injection molded from plastic or can be formed using alternate means and using alternate materials. Recycled plastic minimizes environmental impact and can be more cost-effective than standard materials. The use of plastic in an example embodiment reduces overall weight of the caddy.

Mounting pins 4 extend inwardly from the guides and are located such that the flexible guides 3a and 3b can be extended outward to allow a drive 35 to be inserted into the caddy as shown in FIG. 1D. The mounting pins 4 are located on the guides such that they can engage with one or more cavities, e.g. the screw holes (not shown), of the drive 35. The drive is then secure in the caddy, with the two sides or guides 3 and the cross member 12 surrounding it. Thus, this screw-free mechanism is integrated into a protective enclosure for the drive. A user can easily attach and detach a drive with nominal force via the mounting pins 4 provided, which align with drive holes with precision. The screwless design reduces cost, reduces time required to insert hard drives, and removes the dependency on manufacturing from other countries, should parts such as screws be unavailable domestically.

The handles 2 facilitate hot swapping. the handles can be extended or retracted into open or closed formations. When extended or open, the handles 2, grooved for gripping in this embodiment, can be grasped and used to pull the caddy up and out of a server chassis. Hot swapping without handles 2 is supported, using only nominal force from a user's fingers. Grips 1 are provided for this purpose and can be grooved or have alternate texturing to provide friction for handling. The ends of the guides 3a and 3b are tapered (5) and the edges are filleted (7) for easy and smooth insertion of the caddy into guideways (detailed below) and for smooth removal as well.

FIG. 1C further illustrates the handles 2, each of which comprises flexible members 20 with pins 28 fixed to the end. A pivot point 29 is defined by holes 30 in sidewalls 27 of the handle receptacles. The flexible members 20 can be pinched together to allow the pins 28 to be aligned with the holes 30 and released to secure each handle in place. A cutout 18 on the handle edge allows for the handle to be easily accessed and extended from a closed position. A handle grip 22, formed by texture on each side of the handle in this embodiment, ensures friction to prevent slippage when the handle is being pulled.

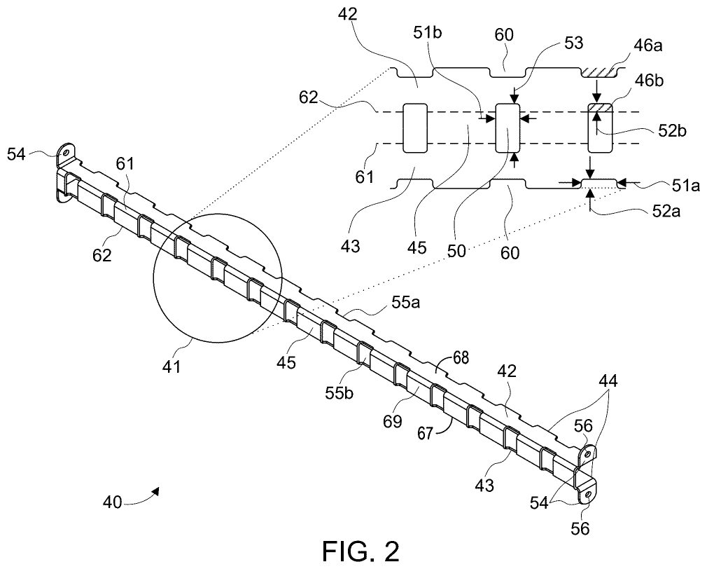

Unidirectional guiding is implemented when both sides 3 differ in width. In FIG. 1C, one side, or guide 3a, has width W1. The other guide 3b has width W2. W1 is not equal to W2 in the example embodiment. A compatible guideway 40 is introduced in FIG. 2 allowing the caddy to be inserted into a chassis in only one orientation. The differing widths of 3a and 3b will prevent the caddy being inserted in an alternate orientation. Unidirectional guide is one feature in the example embodiment, but it is not mandatory. Caddies and guides can have the same size on each side.

FIG. 1C further illustrates the location of grips 1 on each end of the caddy body crossmember 12, which can be simultaneously gripped to insert or remove a caddy from a chassis. A texture such as grooves 16 can be added to facilitate secure gripping.

At least one caddy stop 6 is formed by an overhang of caddy body crossmember 12 relative to an edge of a side 3 defining the stopping edge, or caddy stop 6. As shown in FIG. 1C, the example embodiment has stopping edges 6 on both ends of the crossmember 12. These automatically secure the drive and caddy in place while top loading without the need for any additional locking mechanism. They come to rest on a rail such as a guideway 40 (detailed below). When top-loading, the caddy 10 is inserted straightforwardly in the guideways 40. The user first places the drive into the caddy, ensuring proper alignment with the mounting pins 4 and unidirectional guides 3a and 3b, as shown in FIG. 1D. Then, as the caddy 10 containing the drive 35 is inserted, it is automatically secured in place by stopping edges 6, preventing caddy over-insertion, without the need for any additional locking mechanism. The screwless and springless mechanism ensures that the drive is firmly held within the caddy, providing stable and correct positioning. This tool-free insertion process not only simplifies the task but also reduces the risk of physical damage or data loss during drive swaps.

FIG. 2 depicts the example embodiment of a guideway 40, which is compatible with caddies 10 just described. A guideway 40 is operable with a top-loading caddy 10 having a first guide 3a with a first width and a second guide 3b with a second width. The guideway 40 comprises an elongated body 41 extending along a longitudinal axis, the elongated body 41 having a top surface 42, a bottom surface 43, a first side 44, and a second side 45 opposite the first side 44. A plurality of first notches 55a are formed in the first side 44 of the elongated body 41, each first notch 55a extending transversely from the top surface 42 to the bottom surface 43 and being spaced apart along the longitudinal axis, wherein each notch defines a first contour 46a visible in a top view or a bottom view of the elongated body 41, and wherein each first notch 55a is configured to engage with the first guide 3a, the first contour 46a being shaped to receive the first guide 3a. A plurality of second notches 55b are formed in the second side 45 of the elongated body 41, each second notch 55b extending transversely from the top surface 42 to the bottom surface 43 and being spaced apart along the longitudinal axis, each second notch 55b being aligned with a respective first notch 55a, wherein each second notch 55b defines a second contour 46b visible in a top view or a bottom view of the elongated body 41, and wherein each second notch 55b is configured to engage with the second guide 3b, the second contour 46b of each second notch being shaped to receive the second guide 3b.

The example embodiment of guideway 40 in FIG. 2 has the elongated body 41 formed from a sheet of metallic material bent along the longitudinal axis to define a C-shaped cross-section, the C-shaped cross-section comprising a central web portion 69 connecting two opposing flange portions 67 and 68, wherein the top surface 42 and the bottom surface 43 are defined by upper and lower edges of the central web portion and the top and bottom surfaces of the two opposing flange portions, respectively. First side 44 is defined by outer edges of the two opposing flange portions (67 and 68), the plurality of first notches 55a being formed along the outer edges of the two opposing flange portions. The second side 45 is defined by the central web portion 69 further comprising a plurality of cutouts 50 formed through the central web portion 69 and the two opposing flange portions (67 and 68), each cutout 50 being aligned with a respective first notch 55a, each cutout, once bent, forming one of the plurality of second notches 55b, the second contour 46b defined by a portion of the respective cutout formed in one of the two opposing flange portions.

The top 42 and bottom 43 both have, as a mounting apparatus, brackets 54, which include holes 56 for attaching the guideway to a server chassis. Notches or channels 55 are shown on both sides, which are designed to receive guides 3 of a caddy 10. Notches 55a are sized to receive guides 3a and notches 55b are sized to receive guides 3b. The notches forming channels/notches 55 are filleted.

The C shape of guideway 40 is formed by bending along fold lines 61 and 62. A flat cutout (pre-bend) is shown to illustrate the formation of the notches 55. Notches 55b are formed by introducing cutouts 50 in the pre-folded guideway. Note that the width 51b and notch depth 52b of the cutout 50 is selected to accommodate the width W2 and at least a portion of the thickness of guide 3b plus any tolerance. Notch depths 52b indicate the desired channel depth for receiving guides in notches 55b, determined according to the differences between the top and bottom edges of cutout 50 and fold lines 62 and 61, respectively. The height 53 of the cutout 50 is sized to accommodate the height of the side 45 of the guideway, once folded, plus two notch depths 52b. Notches 55a are formed with a pair of aligned flange notches 60, one from the top flange 67 and one from the bottom flange 68, once the guideway is folded, as shown. The width 51a and depth 52a of notches 60 are designed to comfortably accommodate guides 3a of width W1 plus any tolerance. Using a flange notch pair is optional. A single flange notch may be utilized, so long as the other flange is designed so as not to obstruct the engagement of a guide into the single flange notch.

A C-shape for guideway 40 is selected for a balance of strength and cost-effectiveness. Alternative embodiments could use I-shapes, square beams, or others. These alternates would be adapted to provide a resting edge for stops 6, may have an additional side in which notches 55a would be cut, and other adaptations by those of ordinary skill in the art.

A guideway assembly comprises a plurality of caddy 10 and two or more of the guideways 7. A guideway assembly includes a first guideway and a second guideway parallel to each other and having the first and second plurality of notches of each of the first and second guideways aligned, separated by a distance allowing for a caddy to be inserted into the guideway assembly such that the first guiding side of the caddy engages with one of the first plurality of channels of the first guideway and the second guiding side of the caddy engages with an aligned one of the second plurality of channels of the second guideway.

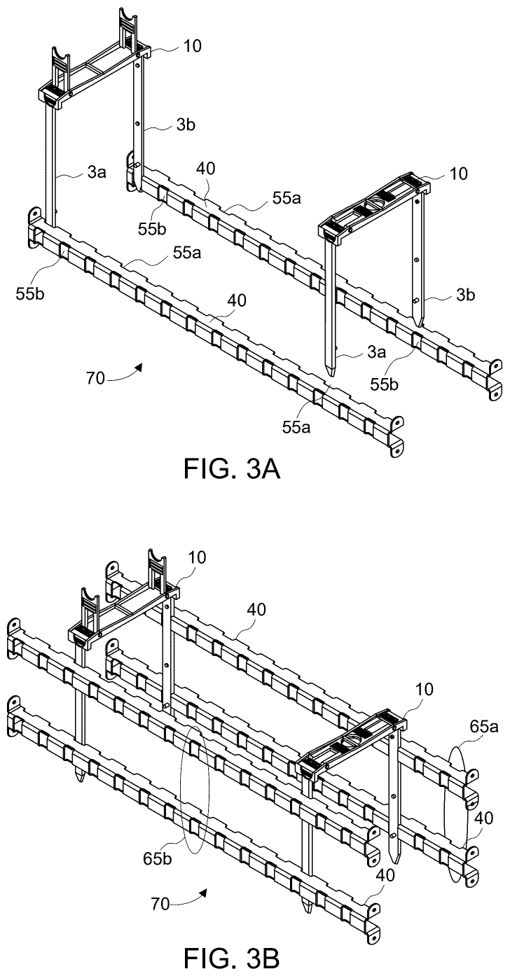

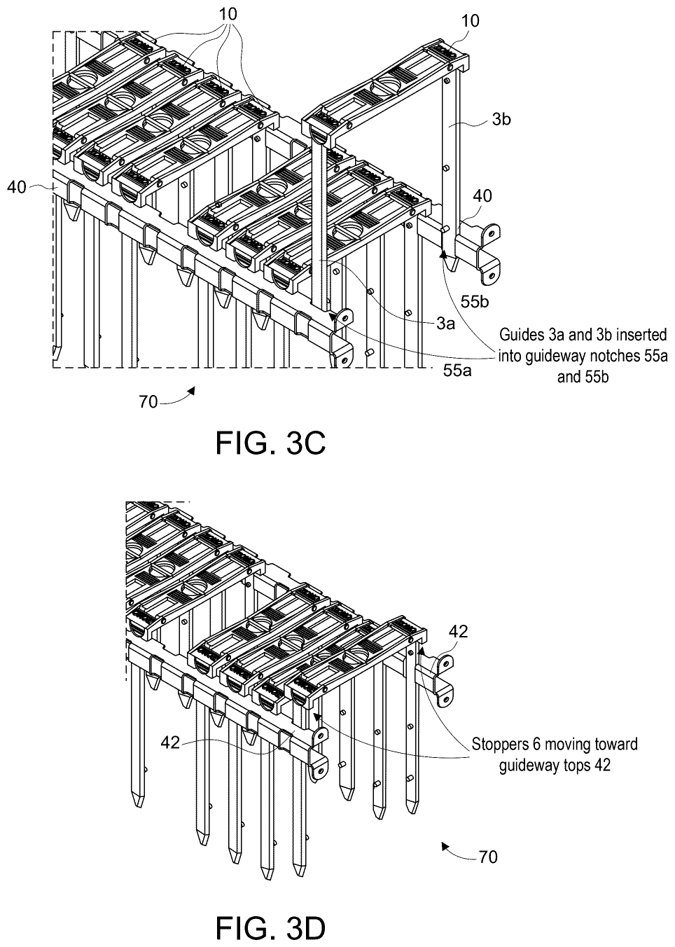

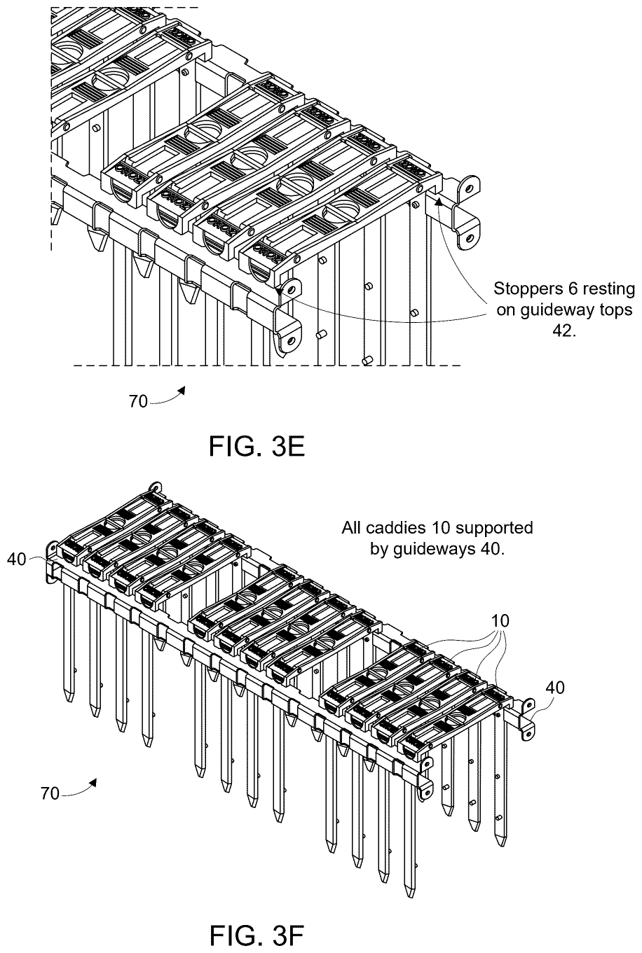

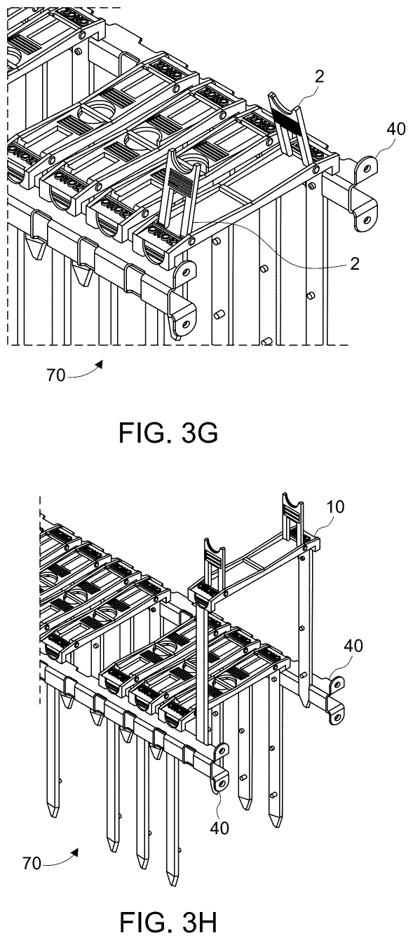

FIGS. 3A-3H illustrate the use of caddies 10 and guideways 40 in a guideway assembly 70. Guideway assemblies 70 may have any number of guideways 40 and caddies 10, and may be incorporated in a server chassis, as illustrated in the example embodiment in FIG. 4A. In these examples, each guideway 40 supports one side of a row of 14 drive caddies 10. The number of notches and channels can be modified to support different numbers or sizes of caddies in alternate embodiments. To support a single row of caddies 10, two guideways 40 are deployed (or sets of guideways, detailed below). To support an additional row of caddies 10, a single guideway 40 (or set) is added. The total number of guideways 40 (which can advantageously all be identical) required to support N rows of caddies is N+1, thus optimizing space in the server chassis. FIG. 4A illustrates an embodiment with 5 sets of guideways supporting 4 rows of caddies.

In FIG. 3A two caddies 10 are shown beginning insertion in two guideways 40. These caddies are empty, for illustrative purposes. A guideway assembly may receive any combination of empty or drive-loaded caddies 10. A first caddy 10 at the right of the guideway assembly 70, with handles 2 closed, is poised just above the guideways 40. Its guide 3a is poised to enter its respective notch 55a. Its guide 3b is poised to enter its respective notch 55b. Note that if the orientation is changed, the caddy will not be able to be inserted, as at least one guide will be larger than its channel, since W1 is not equal to W2 by design. The second caddy 10 at the left of guideway assembly 70, with handles 2 open, has just begun insertion in the guideways 40, with guides 3a and 3b engaging notches 55a and 55b, respectively.

A guideway assembly can further comprise sets of guideways aligned vertically, having their notches aligned, both within the set of guideways, and with a parallel set of guideways. The sets are separated by a distance allowing for a caddy to be inserted into the guideway assembly such that the first guiding side of the caddy engages with one of the first plurality of channels formed in one set and the second guiding side of the caddy engages with an aligned one of the second plurality of channels formed in a second set.

FIG. 3B illustrates the guideway assembly 70 of FIG. 3A, comprising 4 guideways 40. While only two are required, as illustrated in FIG. 3A, alternate embodiments may include an additional row for a variety of reasons, such as additional chassis structural support. The assembly 70 of FIG. 3B will be used in the example illustrated in FIG. 4A. The other FIGS. 3A and 3C-3H show only the top two guideways 40. A channel 65 includes one or more aligned notches. Here a plurality of channels 65a are formed, each channel 65a comprising two aligned notches 55a. Similarly, a plurality of channels 65b are formed, each channel 65b comprising two aligned notches 55b. When a single row of guideways is deployed, as in FIG. 3A, a channel 65a is a single notch 55a, and a channel 65b is a single notch 55b. Here the caddies 10 described above have had continued, but not quite complete, insertion into the guideway assembly 70. Each caddy's guideways 3a and 3b have engaged with the respective channels 65a and 65b of both the top and bottom sets of guideways 40. The insertion is not complete since the stopping edge 6 of either caddy crossmember 12 has not engaged with the top of at least one guideway 40.

FIG. 3C shows the last of a set of caddies 10 being inserted into a guideway assembly 70. Here the guides 3a and 3b have been inserted into the respective channels 65a and 65b. Three other caddies are shown fully inserted, contiguous with the caddy being inserted. Another bank of four caddies 10 is also inserted into the guideway assembly 70, with a slot for a caddy left vacant in between the two banks of caddies. FIG. 3D illustrates the caddy 10 as it is being inserted, approaching its final position, and stoppers 6 are moving toward the tops 42 of each guideway 40. FIG. 3E illustrates the caddy 10 fully inserted, with its stoppers 6 resting on the guideway tops 42. FIG. 3F shows each of 3 banks of caddies 10 fully inserted, each supported by guideways 40, with a vacant slot between each set of banks. This example configuration allows additional airflow between the sets of banks, facilitated by the vacancies.

FIGS. 3G and 3H illustrate removing a caddy 10 via its handles 2. Note that alternatively it could be removed by grasping the grips 1, not shown. The handles 2 are opened as shown in FIG. 2. They can be grasped, and the caddy easily pulled upwards. The caddy 10 nearly removed is illustrated in FIG. 3H.

The foregoing description of the implementations of the present techniques and technologies has been presented for the purposes of illustration and description. This description is not intended to be exhaustive or to limit the present techniques and technologies to the precise form disclosed. Many modifications and variations are possible in light of the above teaching. It is intended that the scope of the present techniques and technologies are not limited by this detailed description. The present techniques and technologies may be embodied in other specific forms without departing from the spirit or essential characteristics thereof. Accordingly, the disclosure of the present techniques and technologies is intended to be illustrative and not limiting. Therefore, the spirit and scope of the appended claims should not be limited to the foregoing description. In U.S. applications, only those claims specifically reciting “means for” or “step for” should be construed in the manner required under 35 U.S.C. § 112(f).

What is claimed is:

1. A server chassis comprising:
A first and second bank of caddies, each bank comprising a plurality of caddies, the banks defining an airflow channel between them;
a plurality of fans disposed at one end of the airflow channel to draw air flow from the opposite end of the airflow channel;
one or more crossmembers, the crossmembers traversing the airflow channel, at least one of the crossmembers supporting the weight of the two banks of caddies; and
an air-diversion device comprising:
a first baffle and a second baffle, the first baffle angled to direct air flow in a first direction, the second baffle angled to direct air flow in a second direction; and
an attachment for affixing the air-diversion device to at least one of the crossmembers such that the air-diversion device is disposed within the airflow channel to divert a first portion of the drawn air to the first bank of caddies in the first direction, to divert a second portion of the drawn air to the second bank of caddies in the second direction, and to allow a third portion of the drawn air to pass above or below the first and second baffles to continue moving in the airflow channel.

2. The server chassis of claim 1, wherein one or more of the one or more crossmembers are guideways.

3. The server chassis of claim 1, the air-diversion device further comprising an aperture defined by an edge of the first baffle and an edge of the second baffle, and wherein the third portion of the drawn air includes air drawn through the aperture.

4. The server chassis of claim 3, further comprising:
a third bank of caddies defining a second airflow channel between the second and third banks of caddies; and
a second air-diversion device comprising third and fourth baffles and a second aperture, the second air-diversion device affixed to at least one of the crossmembers such that the second air-diversion device is disposed within the second airflow channel to divert a fourth portion of the drawn air to the second bank of caddies, to divert a fifth portion of the drawn air to the third bank of caddies, and to allow a sixth portion of the drawn air to pass through the second aperture and above or below the third and fourth baffles to continue moving in the airflow channel.

5. A guideway assembly comprising:
a plurality of caddies including a first set of one or more caddies and a second set of one or more caddies; and
a guideway having a plurality of channels, each of the plurality of channels configured to engage with one of the plurality of caddies, a first set of the plurality of channels for receiving the first set of caddies, a second set of the plurality of channels for receiving the second set of caddies, one or more of the plurality of channels between the first and second sets of caddies remaining vacant of caddies to define an airflow channel between the first and second sets of caddies; and
an air-diversion device having a first baffle angled to direct air flow in a first direction and a second baffle angled to direct a second stream of air flow in a second direction, the air-diversion device attached to the guideway in the airflow channel to divert a first stream of airflow in the first direction to the first bank of caddies, to divert a second stream of airflow in the second direction to the second bank of caddies, and to allow a third stream of airflow around the first and second baffles.

6. The guideway assembly of claim 5, further comprising a second guideway having a second plurality of channels, each of the second plurality of channels configured to engage with one of the plurality of caddies, the second guideway disposed in the airflow channel parallel to the first-mentioned guideway, a first set of the second plurality of channels for receiving the first set of caddies, a second set of the second plurality of channels for receiving the second set of caddies, one or more of the second plurality of channels between the first and second sets of caddies remaining vacant in accordance with the defined airflow channel between the first and second sets of caddies, and wherein the air-diversion device is attached to the first-mentioned guideway and the second guideway.

7. A unitary air-diversion device comprising:
a first baffle having a first surface area angled at a first angle to direct airflow in a first direction;
a second baffle having a second surface area angled at a second angle to direct airflow in a second direction; and
a first side having an edge, the first baffle attached to a first segment of the edge, the second baffle attached to a second segment of the edge, the first and second segments of the edge separated by a third segment of the edge; and
wherein the first baffle, the second baffle, and the third segment of the edge define an aperture.

8. The unitary air-diversion device of claim 7, wherein the aperture defined is rectangular.

9. The unitary air-diversion device of claim 7, wherein the aperture defined is a geometric shape allowing air to pass.

10. The unitary air-diversion device of claim 7, wherein the third segment is not included such that no aperture is defined, the first baffle connecting to the second baffle.

11. The unitary air-diversion device of claim 7, operable with a server drawer comprising a first and second bank of caddies separated to define an airflow channel through which air flow is drawn, the unitary air-diversion device further comprising:
an attachment means for attaching to the server drawer, the attachment means adaptable to attach the air-diversion device in the airflow channel to divert a first stream of airflow in the first direction to the first bank of caddies, to divert a second stream of airflow in the second direction to the second bank of caddies, and to allow a third stream of airflow through the aperture and around the first and second baffles; and wherein:
the first baffle, second baffle, and aperture are sized with respect to the channel surface area to impede a desired fraction of the channel surface area to divert the desired first and second streams of airflow relative to the third stream.

12. The unitary air-diversion device of claim 11 wherein the attachment means is a bracket for affixing to a first guideway of the server drawer.

13. The unitary air-diversion device of claim 12, further comprising:
a second side having a second edge, the first baffle attached to a first segment of the second edge, the second baffle attached to a second segment of the second edge, the first and second segments of the second edge separated by a third segment of the second edge, the third segment of the second edge further defining the aperture; and
a second bracket for affixing to a second crossmember of the server drawer.
